(19) United States
(12) Patent Application Publication
(10) Pub. No.: US 2005/0128003 A1
(43) Pub. Date: Jun. 16, 2005

(54) Transistor assembly

(75) Inventor: Johann-Peter Forstner, Steinhoring (DE)

Correspondence Address: Harold C. Moore;Maginot, Moore & Beck, Bank One Center/Tower, Suite 3000, 111 Monument Circle, Indianapolis, IN, 46204, US

(73) Assignee: Infineon Technologies AG, Munchen (DE)

(21) Appl. No.: 10/943,492

(22) Filed: Sep. 17, 2004

Related U.S. Application Data
(63) Continuation of application No. PCT/EP03/00670, filed on Jan. 23, 2003.

(30) Foreign Application Priority Data
Mar. 19, 2002 (DE) 102 12 165.35

(51) Int. Cl. H03F 3/68

(52) U.S. Cl. 330/295; 330/285

(57) ABSTRACT

A transistor assembly includes a plurality of transistors, a current path for feeding an operating current for the transistor assembly and a plurality of sub-current paths branching off from the current path for feeding a respective operating current for the transistors. A resistor is connected into one of the sub-current paths, wherein a voltage across the resistor is a measure of the operating current of the transistor assembly.

### CROSS-REFERENCE TO RELATED APPLICATION

This application is a continuation of copending International Application No. PCT/EP03/00670, filed Jan. 23, 2003, which designated the United States and was not published in English, and is incorporated herein by reference in its entirety.

### BACKGROUND OF THE INVENTION

1. Field of the Invention

The present invention relates to a transistor assembly and, in particular, to such a transistor assembly comprising a plurality of transistors connected in parallel which together represent a power amplifier.

2. Description of the Related Art

In order to measure the collector current of a bipolar power transistor, a resistor is usually connected into the collector-emitter path. In analogy, in field-effect transistors a resistor is usually connected into the drain-source path in order to measure the drain current.

The resulting circuit structure of a bipolar power transistor 10 is illustrated in FIG. 4. The power transistor 10 includes a plurality of individual transistors of which three transistors 10a, 10b and 10n are shown in FIG. 4. The individual transistors 10a, 10b and 10n are connected in parallel in that the control terminals thereof are connected to an HF input 12 of the transistor assembly, the collector terminals thereof are connected to a voltage source 18 via a resistor 20 and, additionally, connected to an HF output 16 of the transistor assembly, and the emitter terminals thereof are connected to ground. The voltage source represents means for providing the operating current of the power transistor and thus of the individual transistors 10a, 10b and 10n. A resistor 20 is connected between the voltage source 18 and a branching point 24 after which the current supply line branches off to the individual transistors 10, 10b, . . . 10n. Thus, each of the individual transistors 10a, 10b and 10n is effectively connected to this resistor 20. The operating current of the power transistor formed by the sum of the collector-emitter currents of the individual transistors can be detected via the voltage drop at this resistor 20, as is schematically illustrated in FIG. 4 by a voltage-measuring device 22.

In the circuit assembly shown in FIG. 4, the collector resistor 20 results in a reduction of the collector-emitter voltage of each of the individual transistors and the controllability thereof is impeded. Additionally, loss power is generated in the resistor 20. In particular in applications operating at a small supply voltage, such as, for example, in mobile radio or in power amplifiers, this can result in a significant impairment of the output power of the transistor assembly and the efficiency thereof. Consequently, the transmitting time of a battery-operated mobile phone will be reduced.

### SUMMARY OF THE INVENTION

It is the object of the present invention to provide a transistor assembly offering a simple low-loss possibility to provide a measure of the operating current of one or several transistors of the transistor assembly.

In accordance with a first aspect, the present invention provides a transistor assembly having: a plurality of transistors connected in parallel, the control terminals of which are connected to a common HF input; a current path for feeding an operating current for the transistor assembly; a plurality of sub-current paths branching off from the current path for feeding a respective operating current for the transistors; a resistor connected into one of the sub-current paths, wherein a voltage across the resistor is a measure of the operating current of the transistor assembly; and means for regulating the operating current of the transistor assembly based on the voltage across the resistor.

The present invention is based on the finding that it is possible to effectively connect only one of the transistors to a resistor for detecting the operating current of a transistor assembly formed of a plurality of transistors and to detect the voltage across this resistor to act as a measure of the operating current of the entire transistor assembly. This is possible since the operating current through the transistor effectively connected to the resistor and the operating current of the other transistors have a determined relation to one another.

The voltage across the resistor is a measure of the operating current of the entire transistor assembly and, additionally, a measure of the operating currents of the individual transistors since the operating current of the transistor assembly is formed by the sum of the collector-emitter currents (operating currents) of the individual transistors.

According to the invention, only the performance of the one transistor which is effectively connected to the resistor and can thus be considered as an auxiliary transistor is impeded by the wiring to the resistor. In addition, the loss power in the resistor is considerably smaller than in wiring the entire transistor assembly to the resistor, i.e. when-providing the resistor in the current path conducting the operating current of the entire transistor assembly.

The present invention can be applied with particular advantage in power transistors which basically include several, sometimes up to several hundred, individual transistors connected in parallel. In these power transistors, all the transistor terminals are usually merged on busses, wherein all the individual transistors which are also referred to as transistor fingers are lined up in a spatially close relation on a semiconductor chip and thus comprise almost identical electrical features. Thus, an individual transistor, i.e. a transistor finger, represents the features of the entire power transistor. If the detection of a measure of the operating current of this individual transistor is made possible, conclusions can be drawn to the operating current of the remaining transistors of the power transistor.

In such an application of the present invention to a power transistor including many individual transistors connected in parallel, the current determination takes place more or less without power. Since additionally only the electrical features of the effectively connected individual transistor but not the electrical features of all the other transistors of the power transistor are influenced, the electrical characteristics of the entire power transistor are hardly influenced.

Preferably, the individual transistor effectively connected to the resistor is completely HF (high-frequency) coupled to the entire transistor, i.e. base, collector and emitter conduct almost exactly the same HF signals as corresponding transistor terminals of the transistors not connected effectively, which is the case when connecting in parallel a plurality of transistors in power transistors. In such a design, changes in the surroundings of the entire transistor, such as, for example, mismatching at the HF output, are also reflected by a changed current consumption in the transistor effectively connected to the resistor.

In preferred embodiments of the present invention, means is further provided to adjust the operating current of the power transistor and thus the respective operating currents of the individual transistors thereof based on the voltage across the resistor. In particular, the operating current of the entire transistor can be controlled to a constant value based on the voltage across the resistor.

### BRIEF DESCRIPTION OF THE DRAWINGS

Preferred embodiments of the present invention will be detailed subsequently referring to the appendage drawings, in which:

FIG. 1 shows a circuit diagram of an inventive transistor assembly;

FIG. 2 shows a circuit diagram of an inventive transistor assembly having operating current regulation;

FIG. 3 shows a circuit diagram of an alternative inventive transistor assembly having operating current regulation; and

FIG. 4 shows a circuit diagram of a conventional transistor assembly.

### DESCRIPTION OF PREFERRED EMBODIMENTS

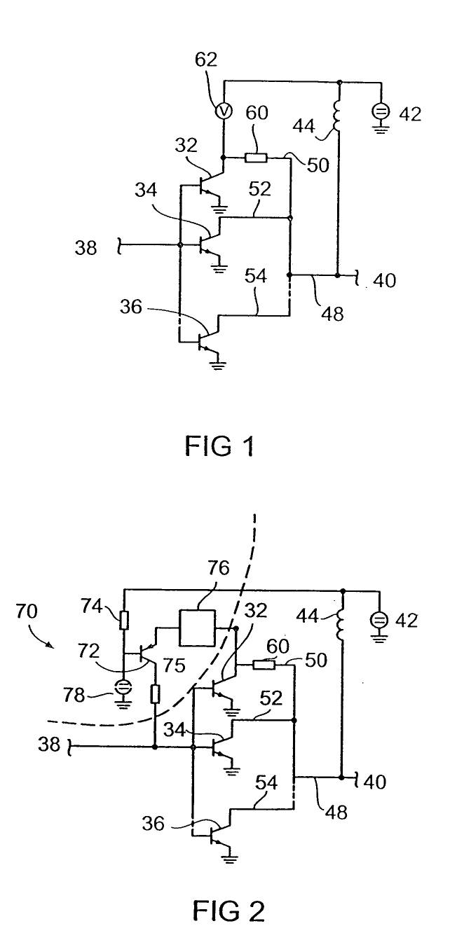

Preferred embodiments of the present invention will be detailed subsequently referring to FIGS. 1 to 3 with the example of bipolar power transistors. It is to be pointed out here that the present invention can be applied in the same manner to field-effect transistors having gate, drain and source instead of base, collector and emitter.

As is shown in FIG. 1, the embodiment of the inventive transistor assembly illustrated includes a plurality of bipolar transistors 32, 34 and 36. The bipolar transistors 32, 34 and 36 are connected in parallel and together form a power transistor which, as the interrupted lines in FIG. 1 show, is usually formed by a considerably greater number, such as, for example, several hundred, of individual transistors.

The bipolar transistors 32, 34 and 36 are connected in parallel in that the base terminals, i.e. the control terminals, thereof are connected to an HF input 38, the emitter terminals thereof are connected to ground and the collector terminals thereof are coupled to an HF output 40. An operating current of the transistor assembly is provided by a voltage source 42 which is connected to a current path 48 conducting the entire operating current for the transistor assembly via a coil 44 serving for HF decoupling. The current path 48 branches off into individual sub-lines 50, 52 and 54 or sub-current paths, respectively, which are connected to the collector terminals of the transistors 32, 34 and 36.

As can be seen in FIG. 1, the collector terminals of the transistors 34 and 36 are directly connected to the current path 48 via the sub-lines 52 and 54, while a resistor 60 is connected into the sub-line 50. In addition, for purposes of illustration, a voltage-measuring device 62 enabling detection of the voltage across the resistor 60 is shown, since the coil 44 represents a short circuit for the direct current considered. As an alternative to the coupling illustrated, the current-measuring device 62 could be directly connected in parallel to the resistor 60.

In the transistor assembly shown in FIG. 1, the voltage source 42 provides an operating current for the entire transistor assembly via the coil 44 on the current path 48. This total current branches off into individual partial currents fed to the individual transistors on the sub-lines 50, 52 and 54 at the branching point of the current path 48. The partial current fed to the transistor 32 can be detected by the resistor 60 connected into the sub-line 50 by detecting a voltage across it. According to the invention, the resistor 60 is not connected into the current path conducting the entire operating current of the transistor assembly but into the current path carrying the operating current of just one individual transistor.

The currents through the lines 50, 52 and 54 are in a determined relation to one another due to the current divider resulting by the branching of the current path 48 into the sub-current paths 50, 52 and 54 and due to the wiring of the respective sub-lines. Thus, conclusions can be drawn to the currents through the conductors 52 and 54 from the voltage across the resistor 60. In addition, the entire operating current or the operating currents of the individual transistors, respectively, can be additionally controlled by controlling the voltage across the resistor 60.

In the circuit assembly shown in FIG. 1, the auxiliary transistor finger, i.e. the transistor 32 having the resistor 60, is completely HF-coupled to the entire transistor, i.e. base, collector and emitter conduct nearly exactly the same high-frequency signals as the corresponding transistor terminals of the remaining transistors. The only difference here is a small amplification provided by the auxiliary transistor 32, due to the change of the operating point thereof by the wiring to the resistor 60. This effect can, however, be neglected, wherein nevertheless changes in the surroundings of the entire transistor, such as, e.g., a mismatch of the output 40 of it, are reflected by a changed current consumption in the auxiliary transistor.

FIG. 2 shows an embodiment of the present invention comprising means for regulating the operating current of the power transistor based on the voltage across the resistor 60. Thus, in FIG. 2 elements corresponding to those of FIG. 1 are designated by the same reference numerals.

According to FIG. 2, the voltage-measuring device 62 schematically illustrated in FIG. 1 is substituted by a regulating element 70 by which the voltage drop at the resistor 60 can be kept constant so that the operating current of the entire transistor, too, is kept constant.

The regulating element 70 includes a transistor 72, resistors 74 and 75, a loop low-pass filter 76 and a constant current source 78. In the embodiment illustrated, the transistor 72 is a pnp transistor while the transistors 32, 34 and 36 are npn transistors.

The emitter terminal of the transistor 72 is connected to the collector terminal of the transistor 32 via the loop low-pass filter 76. The collector terminal of the transistor 72 is connected to the base terminal of the transistors 32, 34 and 36 via the resistor 75. The base terminal of the transistor is connected to ground via the constant current source 78 and connected to the voltage source 42 via the resistor 74. The constant current source 78 provides a defined voltage drop at the resistor 74 with an offset by the voltage source 42.

For explaining the mode of functioning of the regulating element 70, it is assumed that the operating current has a predetermined value resulting in a certain voltage drop at the resistor 60. If the operating current changes, the voltage across the resistor 60 and thus the potential at the emitter terminal of the transistor 72 will change, wherein high-frequency changes are blocked by the loop low-pass filter 76.

More precisely, the potential at the emitter terminal of the transistor 72 will decrease if the voltage drop at the resistor 60 increases, while the potential at the emitter terminal of the transistor 72 will increase if the voltage drop at the resistor 60 decreases.

The base-emitter voltage and thus the collector-emitter current of the transistor 72 decrease by a reduced potential at the emitter terminal of the transistor 72. Thus, the base current available for the transistors 32, 34 and 36 is reduced so that the operating current thereof, i.e. the collector-emitter current thereof, will decrease. Thus, the current through the resistor 60 and consequently the voltage drop over it will be reduced.

The base emitter voltage and thus the collector-emitter current, however, will increase by an increased potential at the emitter terminal of the transistor 72, as is caused by a reduced voltage drop at the resistor 60. Thus, the base current available for the transistors 32, 34 and 36 will increase so that the operating current thereof, i.e. the collector-emitter current thereof, will increase. Consequently, the current through the resistor 60 and the voltage drop across it will increase.

According to the above explanations, the operating current through the entire transistor is regulated to a constant value by the regulating element 70 shown in FIG. 2.

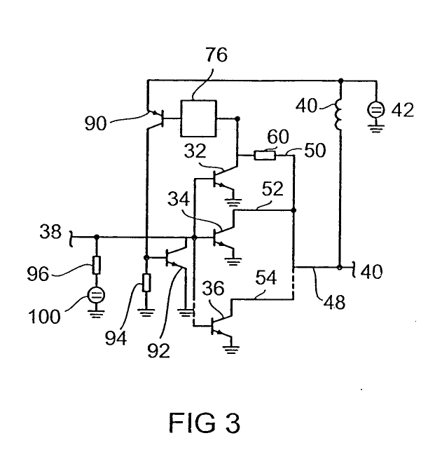

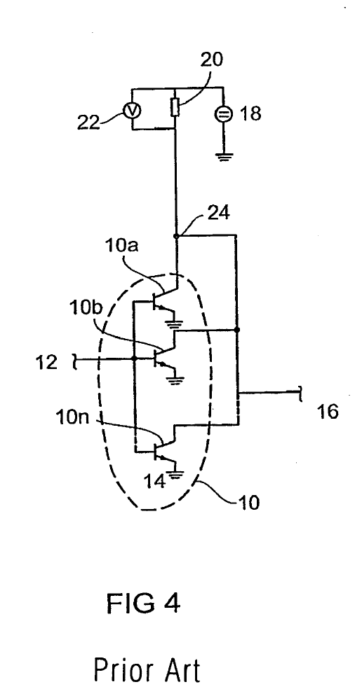

Another embodiment for regulating the operating current of the transistor assembly is shown in FIG. 3, which again illustrates a regulating element by which the voltage drop at the resistor 60 can be kept constant so that the operating current of the entire transistor is kept constant, too.

The regulating element shown in FIG. 3 includes a loop low-pass filter 76, a pnp transistor 90, an npn transistor 92, resistors 94 and 96 and a voltage source 100. The loop filter 76 is connected between the collector terminal of the transistor 32 and the base terminal of the pnp transistor 90. The emitter terminal of the pnp transistor 90 is connected to the voltage source 42. The collector terminal of the pnp transistor 90 is connected to ground via the resistor 94. In addition, the collector terminal of the pnp transistor 90 is connected to the base terminal of the npn transistor 92. The emitter terminal of the transistor 92 is connected to ground and the collector terminal thereof is connected to the base terminal of the transistors 32, 34 and 36. Finally, a series connection of the resistor 96 and the voltage source 100 is connected between the base terminal of the transistors 32, 34 and 36 and ground.

The regulation of the operating current by the above setup will be explained subsequently. If the operating current of the transistor assembly changes departing from a desired operating current, the voltage across the resistor 60 will change. Due to this, the potential at the base terminal of the pnp transistor 90 will change, wherein high-frequency changes will be blocked by the loop low-pass filter 76. More explicitly, the potential at the base terminal of the transistor 90 will decrease if the voltage drop across the resistor 60 increases, and vice-versa. The collector-emitter current will change due to the changed potential at the base terminal of the transistor 90. More precisely, the collector-emitter current through the transistor 90 will increase if the potential at the base terminal thereof decreases, and vice-versa.

The change of the collector-emitter current of the transistor will change the voltage drop across the resistor 94 and thus the potential at the base of the resistor 92. Thus, the collector-emitter current of the transistor 92 and consequently the current consumed by this transistor from the base current of the transistors 32, 34 and 36 will change. Consequently, the base current of the transistors 32, 34 and 36 will be reduced if the voltage drop across the resistor 60 and thus the voltage drop across the resistor 94 increase, while the base current in the transistors 32, 34 and 36 will increase if the voltage drop across the resistor 60 and thus the voltage drop across the resistor 94 decrease.

Corresponding to the change of the base current of the transistors 32, 34 and 36, the emitter-collector current consumed by them and thus the operating current of the transistor assembly will change. The operating current is also regulated to a constant value in the example shown in FIG. 3.

It is to be pointed out here that the regulating elements described referring to FIGS. 2 and 3 only represent examples and that a plurality of modified regulating elements is obvious to those skilled in the art. The intervention in the regulation can thus take place both in the bias of the power transistor, i.e. the individual transistors thereof, or else in an amplifier upstream of the power transistor acting as an output stage transistor. Here, the input line of the output stage transistor can be reduced so that the current consumption thereof will decrease.

Apart from a constant current regulation, as has been explained above referring to FIG. 2, different current regulations operating on the basis of the voltage across the resistor 60 can be realized. It is, particularly, possible to provide a regulation offering a current limitation and thus overload protection. This can be of advantage in power transistors, in particular in mobile radio where there are often high collector currents. Such high collector currents can, for example, be caused by mismatching at the output, wherein the transistor may be damaged by these high collector currents. The collector current of all the transistors of a power transistor can be limited to a defined maximum value using a suitable regulating element based on the voltage across the resistor which only the auxiliary transistor finger is connected to. A permanent damage of the power transistor can thus be prevented.

In addition, the present invention can be employed to perform a high-frequency output power limitation and a high-frequency output power setting. In order to optimize the efficiency, high-frequency power output stages are often operated in an AB, B and C operation, depending on the operating point setting. In these modes of operation, there is a very precise context between output stage current, i.e. operating current of the high-frequency power output stage, and the high-frequency output power. If the transistors of such a power output stage are compressed as a consequence of a high input power, the high-frequency output power can be set through a collector current limitation, which again takes place on the basis of the voltage across the resistor connected according to the invention.

Apart from the embodiments mentioned above, any current regulation can be performed by the remaining transistor fingers on the basis of detecting the current through an auxiliary transistor finger, as is performed according to the invention, since the currents through the different fingers have a reproducible relation to one another. The present invention thus provides the possibility to provide an operating current regulation for transistor assemblies having a plurality of transistors, which, on the one hand, does not reduce significantly the collector-emitter voltages of the individual transistors, except for the transistor effectively connected to the resistor, and, on the other hand, only generates small loss power. According to the invention, this is made possible by not wiring the entire power transistor to the resistor, but only an individual transistor, i.e. individual transistor finger, of the plurality of transistors.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1-5. (canceled)

6. A transistor assembly comprising:
a plurality of transistors connected in parallel, each of the plurality of transistors including a control terminal, and each of the control terminals connected to a common HF input;
a current path operable to feed an operating current for the transistor assembly;
a plurality of sub-current paths branching off from the current path, each of the plurality of sub-current paths operable to feed an operating current for one of the plurality of transistors;
a resistor connected in one of the plurality of sub-current paths, wherein a voltage across the resistor is a measure of the operating current of the transistor assembly; and
a regulator operable to regulate the operating current of the transistor assembly based on the voltage across the resistor.

7. The transistor assembly according to claim 6, wherein the regulator is operable to adjust the amplification of the plurality of transistors based on the voltage across the resistor.

8. The transistor assembly according to claim 7, wherein the regulator is operable to adjust the amplification of the plurality of transistors such that the operating current of the transistor assembly is regulated to a constant value.

9. The transistor assembly according to claim 8, wherein the regulator comprises a regulator transistor having a control input and the potential at the control input of the regulator transistor is dependent on the voltage across the resistor.

10. The transistor assembly according to claim 9, wherein the regulator is operable to adjust the amplification of the plurality of transistors such that the operating current of the transistor assembly does not exceed a maximum value.

11. A transistor assembly comprising:
a plurality of transistors connected in parallel, each of the plurality of transistors including a control terminal, and each of the control terminals connected to a common HF input;
a current path operable for feeding an operating current for the transistor assembly;
a plurality of sub-current paths branching off from the current path, each of the plurality of sub-current paths for feeding an operating current for one of the plurality of transistors;
a resistor connected in one of the plurality of sub-current paths, wherein a voltage across the resistor is a measure of the operating current of the transistor assembly; and
means for regulating the operating current of the transistor assembly based on the voltage across the resistor.

12. The transistor assembly according to claim 11, wherein the means for regulating the operating current of the transistor assembly comprises a means for adjusting the amplification of the plurality of transistors based on the voltage across the resistor.

13. The transistor assembly according to claim 12, wherein the means for adjusting the amplification of the plurality of transistors adjusts the amplification of the plurality of transistors such that the operating current of the transistor assembly is regulated to a constant value.

14. The transistor assembly according to claim 13, wherein the means for adjusting the amplification of the plurality of transistors comprises a regulator transistor having a control input and the potential at the control input of the regulator transistor is dependent on the voltage across the resistor.

15. The transistor assembly according to claim 14, wherein the means for adjusting the amplification of the plurality of transistors adjusts the amplification of the plurality of transistors such that the operating current of the transistor assembly does not exceed a maximum value.

16. A method for regulating the operating current of a transistor assembly comprising:
providing a plurality of transistors connected in parallel, each of the plurality of transistors including a control terminal, and each of the control terminals connected to a common input;
providing a current path for feeding the operating current in the transistor assembly;
providing a plurality of sub-current paths branching off from the current path, each of the plurality of sub-current paths for feeding a partial operating current to one of the plurality of transistors;
providing a resistor connected in one of the plurality of sub-current paths, wherein a voltage across the resistor is a measure of the operating current of the transistor assembly; and
regulating the operating current of the transistor assembly based on the voltage across the resistor.

17. The method of claim 16 wherein the step of regulating the operating current of the transistor assembly comprises adjusting the amplification of the plurality of transistors based on the voltage across the resistor.

18. The method of claim 17 wherein the step of adjusting the amplification of the plurality of transistors comprises adjusting the amplification of the plurality of transistors such that the operating current of the transistor assembly is regulated to a constant value.

19. The method of claim 18 wherein the step of adjusting the amplification of the plurality of transistors comprises providing a regulator transistor having a control input and adjusting the potential at the control input of the regulator transistor depending on the voltage across the resistor.

20. The method of claim 19 wherein the step of adjusting the amplification of the plurality of transistors comprises adjusting the amplification of the plurality of transistors such that the operating current of the transistor assembly does not exceed a maximum value.
